(19) United States
(12) Patent Application Publication
(10) Pub. No.: US 2012/0267660 A1
(43) Pub. Date: Oct. 25, 2012

(54) ORGANIC LIGHT EMITTING DIODE DISPLAY

(75) Inventors: Byung-Uk HAN, Yongin-City (KR); Eui-Jin YOO, Yongin-City (KR); Jae-Yong KIM, Yongin-City (KR); Chul-Woo JEONG, Yongin-City (KR); Seon-Hee KIM, Yongin-City (KR); Byung-Hoon CHAE, Yongin-City (KR); Gun-Mo KIM, Yongin-City (KR)

(73) Assignee: SAMSUNG MOBILE DISPLAY CO., LTD., Yongin-City (KR)

(21) Appl. No.: 13/323,705

(22) Filed: Dec. 12, 2011

(30) Foreign Application Priority Data
Apr. 21, 2011 (KR) 10-2011-0037379

(51) Int. Cl. H01L 51/52; H01L 51/56

(52) U.S. Cl. 257/98; 438/27; 257/E51.018; 257/E51.001

(57) ABSTRACT

An organic light emitting diode (OLED) display includes: a display substrate; an organic light emitting element formed over the display substrate; a thin film encapsulation layer formed over the display substrate to cover the organic light emitting element; an encapsulation member facing the display substrate with the organic light emitting element and the thin film encapsulation layer therebetween; a sealant surrounding the organic light emitting element and the thin film encapsulation layer disposed between the display substrate and the encapsulation member, and bonding the display substrate and the encapsulation member; and a light control member disposed between the encapsulation member and the thin film encapsulation layer.

### RELATED APPLICATIONS

This application claims priority to and the benefit of Korean Patent Application No. 10-2011-0037379 filed in the Korean Intellectual Property Office on Apr. 21, 2011, the entire contents of which are incorporated herein by reference.

### BACKGROUND

1. Field

The present disclosure relates generally to an organic light emitting diode (OLED) display. More particularly, the present disclosure relates to an organic light emitting diode (OLED) display for improving an encapsulation configuration.

2. Description of the Related Art

OLED displays are flat panel displays that can be made lightweight and thin because they have self-luminous characteristics and require no separate light source. Particularly, since the OLED displays exhibit high quality characteristics such as low power consumption, high luminance, high response speed, and thus, the OLED displays receives much attention as next-generation display devices.

An OLED display includes a plurality of organic light emitting diodes including a hole injection electrode, an organic emission layer, and an electron injection electrode. The organic light emitting element emits light by energy that occurs when excitons generated by combination of electrons and holes in the organic emission layer enter the ground state from the exited state, and the organic light emitting diode display uses such light emission to display images.

However, the organic emission layer sensitively reacts to the external environment such as to moisture and oxygen. Therefore, when the organic emission layer is exposed to moisture and oxygen, the quality of the organic light emitting diode display is deteriorated. As a result, in order to protect the organic light emitting diode and prevent the moisture or oxygen from penetrating the organic emission layer, a sealing substrate is attached to a substrate body in an airtight manner through a sealing process to seal the organic light emitting diode, or a thin film encapsulation layer is formed on the organic light emitting diode.

The encapsulation substrate is bonded with the display substrate by using a sealant made of a frit material with excellent vapor transmission resistance. However, the frit is relatively easily damaged by an impact to reduce stability.

Further, when the thin film encapsulation layer is used, vapor transmission resistance of the thin film encapsulation layer may be relatively insufficient at the side of the device.

The above information disclosed in this Background section is only for enhancement of understanding of the background of the described technology and therefore it may contain information that does not form the prior art that is already known in this country to a person of ordinary skill in the art.

### SUMMARY

One aspect of the subject matter is to provide an organic light emitting diode (OLED) display for improving durability and vapor transmission resistance, efficiently suppressing reflection of external light, and effectively adding an element such as a touch sensor.

An embodiment provides an organic light emitting diode display which may include: a display substrate; an organic light emitting element formed over the display substrate; a thin film encapsulation layer formed over the display substrate to cover the organic light emitting element; an encapsulation member facing the display substrate with the organic light emitting element and the thin film encapsulation layer therebetween; a sealant surrounding the organic light emitting element and the thin film encapsulation layer, disposed between the display substrate and the encapsulation member, and bonding the display substrate and the encapsulation member; and a light control member disposed between the encapsulation member and the thin film encapsulation layer, the light control member is configured to suppress a reflection of external light.

The light control member may include a polarizing member.

The light control member may include a light blocking pattern layer.

The encapsulation member may be a substrate made of glass.

The encapsulation member may be a film made of a resin-based material.

The sealant may include an epoxy-based material.

A plurality of the organic light emitting elements, a plurality of the thin film encapsulation layers, and a plurality of the light control members may be formed over a single mother substrate divided into a plurality of regions which are to form a plurality of the display substrates.

The encapsulation member may be bonded to the mother substrate using the plurality of sealants to form an unfinished product, which is then cut at regions positioned between the sealants surrounding the different organic light emitting elements to divide the device into a plurality of the organic light emitting diode displays.

The organic light emitting diode display may further include a touch sensor disposed between the organic light emitting element and the thin film encapsulation layer.

The organic light emitting diode display may further include a touch sensor disposed between the light control member and the thin film encapsulation layer. The encapsulation member includes a dent that is formed on a surface facing the organic light emitting element, and further includes a touch sensor formed in the dent of the encapsulation member.

The encapsulation member may further include an additional dent formed on the surface facing the sealant, and one end of the sealant may be received in the additional dent.

The organic light emitting diode display may further include a touch sensor formed over a surface of the encapsulation member facing away from the organic light emitting element.

The organic light emitting diode display may further include a protection window coupled to the encapsulation member with the touch sensor therebetween.

According to an embodiment, the organic light emitting diode (OLED) display improves durability and vapor transmission resistance, efficiently suppresses reflection of external light, and effectively adds an element such as a touch sensor.

### BRIEF DESCRIPTION OF THE DRAWINGS

FIG. 1 shows a cross-sectional view of an organic light emitting diode (OLED) display according to a first embodiment.

FIG. 2 shows a cross-sectional view of an organic light emitting diode (OLED) display according to a second embodiment.

FIG. 3 shows a cross-sectional view of an organic light emitting diode (OLED) display according to a third embodiment.

FIG. 4 shows a cross-sectional view of an organic light emitting diode (OLED) display according to a fourth embodiment.

FIG. 5 shows a cross-sectional view of an organic light emitting diode (OLED) display according to a fifth embodiment.

FIG. 6 shows a cross-sectional view of an organic light emitting diode (OLED) display according to a sixth embodiment.

FIG. 7 shows a cross-sectional view of an organic light emitting diode (OLED) display according to a seventh embodiment.

FIG. 8 shows a cross-sectional view of an organic light emitting diode (OLED) display according to an eighth embodiment.

### DETAILED DESCRIPTION

Embodiments of the present invention will be described more fully hereinafter with reference to the accompanying drawings, in which embodiments of the invention are shown. As those skilled in the art would realize, the described embodiments may be modified in various different ways, all without departing from the spirit or scope of the present invention.

Further, like reference numerals denote like components throughout several embodiments. A first embodiment will be representatively described, and then only components other than those of the first embodiment will be described in other embodiments.

The drawings and description are to be regarded as illustrative in nature and not restrictive. Like reference numerals designate like elements throughout the specification.

In addition, the size and thickness of each component shown in the drawings are arbitrarily shown for ease of understanding and description, but the present invention is not limited thereto, and in the drawings, the thickness of layers, films, panels, regions, etc., may be exaggerated for clarity. It will be understood that when an element such as a layer, film, region, or substrate is referred to as being “on” another element, it can be directly on the other element or intervening elements may also be present.

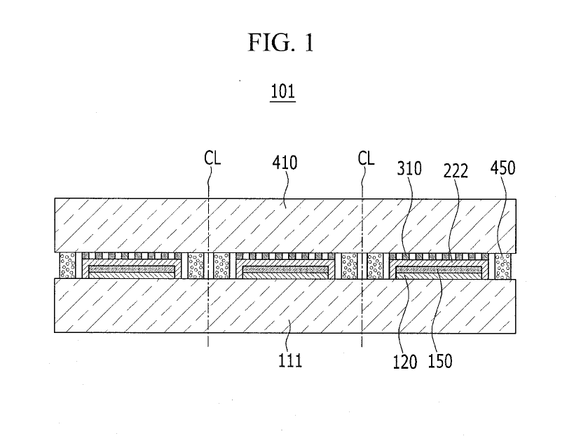

Referring to FIG. 1, an organic light emitting diode (OLED) display 101 according to a first embodiment will now be described.

As shown in FIG. 1, the organic light emitting diode (OLED) display 101 includes a display substrate 111, a driving circuit 120, an organic light emitting element 150, a thin film encapsulation layer 222, a light blocking pattern layer 310, a sealant 450, and an encapsulation member 410.

The display substrate 111 is formed with a transparent insulation substrate made of glass, quartz, or ceramic.

The driving circuit 120 is formed on the display substrate 111. The driving circuit 120 includes a plurality of thin film transistors and capacitors and drives the organic light emitting element 150.

The organic light emitting element 150 is formed on the display substrate 111, and is electrically connected to the driving circuit 120. The organic light emitting element 150 outputs light in response to a driving signal provided by the driving circuit 120. In this instance, the organic light emitting diode display 101 can be classified as a light emitting area and a non-light emitting area around the light emitting area.

The driving circuit 120 and the organic light emitting element 150 can be formed in various types of configurations known to a person skilled in the art.

The thin film encapsulation layer 222 covers the organic light emitting element 150 to protect the same. The thin film encapsulation layer 222 includes at least one of an inorganic layer and an organic layer. When the thin film encapsulation layer 222 is formed by alternately stacking the at least one of an inorganic layer and an organic layer, merits and drawbacks of the inorganic layer and the organic layer can be supplemented. In detail, the inorganic layer has vapor transmission suppressing performance better than the organic layer, and the organic layer has a relatively better smoothing characteristic and can reduce interlayer stress. In an embodiment, the entire thickness of the thin film encapsulation layer 222 can be 1 to 1000 nm thick.

The light blocking pattern layer 310 which can function as one of a light control members is disposed between the thin film encapsulation layer 222 and the encapsulation member 410. That is, when the organic light emitting diode (OLED) display 101 is used in a bright place, the light blocking pattern layer 310 suppresses deterioration in expression of black and deterioration of contrast caused when the external light is reflected from the inside of the organic light emitting diode (OLED) display 101.

The light blocking pattern layer 310 is classified as a light transmitting area and a light blocking area. The light blocking area of the light blocking pattern layer 310 is formed to generally correspond to the non-light emitting area of the organic light emitting diode display 101 and is formed with a pattern similar to a matrix.

The encapsulation member 410 disposed to oppose the display substrate 111 with the organic light emitting element 150 and the thin film encapsulation layer 222 therebetween. In the first embodiment, a substrate made of glass is the encapsulation member 410.

The sealant 450 is disposed between the display substrate 111 and the encapsulation member 410 to surround the organic light emitting element 150 and the thin film encapsulation layer 222. The display substrate 111 and the encapsulation member 410 are bonded by the sealant 450 to seal the insider of the display 101.

Also, in the first embodiment, the sealant 450 is made of an epoxy-based material.

The organic light emitting diode (OLED) display 101 according to the first embodiment is formed by forming a plurality of organic light emitting elements 150, a plurality of thin film encapsulation layers 222, and a plurality of light blocking pattern layers 310 on a single mother substrate that is separated into a plurality of display substrates 111, bonding the encapsulation member 410 through a plurality of sealants 450, and cutting areas that are located between the sealants 450 surrounding different organic light emitting elements 150.

During the above-noted cutting process, the sealant 450 protects the organic light emitting element 150 and suppresses generation of problems. Particularly, since the sealant 450 is made of an epoxy-based material, generation of problems such as breaking can be more efficiently suppressed.

By the above-described configuration, the organic light emitting diode (OLED) display 101 according to the first embodiment can have a configuration for controlling reflection of external light and improving durability and vapor transmission resistance.

In embodiments, the encapsulation member 410 and the sealant 450 supplement the vapor transmission resistance of the thin film encapsulation layer 222 and improve mechanical strength of the organic light emitting diode (OLED) display 101 to supplement durability.

The thin film encapsulation layer 222 is relatively weak with regard to moisture that enters from the side direction. However, according to the first embodiment, the vapor transmission resistance can be supplemented by the sealant 450 surrounding the thin film encapsulation layer 222.

Also, the thin film encapsulation layer 222 is formed inside the space sealed by the sealant 450 and the encapsulation member 410 so the sealant 450 can be made with an epoxy-based material that is relatively inexpensive. Compared to the sealant made of the frit material, the sealant 450 made of the epoxy-based material has somewhat low vapor transmission resistance but the organic light emitting element 150 is protected with the thin film encapsulation layer 222, too, so the frit material that is relatively expensive does not need to be used for the sealant 450. Further, the use of the sealant 450 made of the epoxy-based material can reduce the drawback of easy breaking caused by an external impact when the sealant made of frit is used.

Also, the light blocking pattern layer 310 that is a light control member is disposed between the thin film encapsulation layer 222 and the encapsulation member 410. Thus, damages of the organic light emitting element 150 that can be occurred during forming of the light blocking pattern layer 310 can be minimized. And, the encapsulation member 410 can efficiently protect the light blocking pattern layer 310 from being damaged or contaminated.

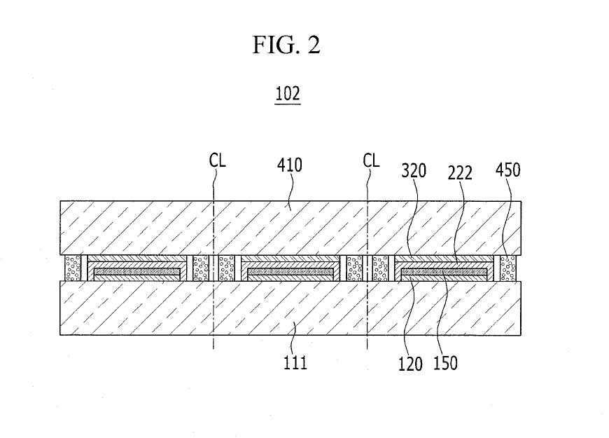

A second embodiment will now be described with reference to FIG. 2.

As shown in FIG. 2, the organic light emitting diode (OLED) display 102 according to the second embodiment uses a polarizing member 320 as a member for suppressing reflection of external light.

The polarizing member 320 includes a plurality of optical films such as a polarizing plate and a phase delay plate, and it can have various types of configurations known to a person skilled in the art. The polarizing member 320 can suppress the reflection of the external light more effectively than the light blocking pattern layer 310 used in the first embodiment.

In the second embodiment, the polarizing member 320 is protected by using the encapsulation member 410 so that the damage and contamination of the polarizing member 320 can be minimized in an efficient manner.

By the above-described configuration, the organic light emitting diode (OLED) display 102 according to the second embodiment can efficiently suppress reflection of external light and improve durability and vapor transmission resistance.

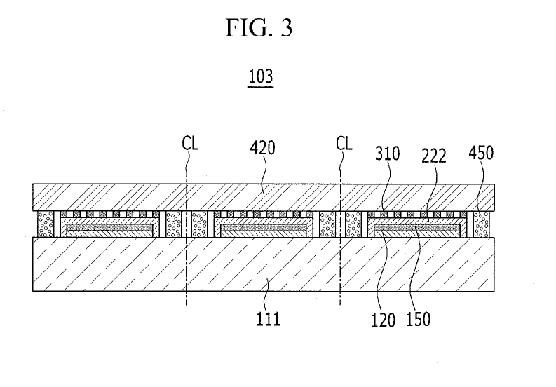

Referring to FIG. 3, a third embodiment will now be described.

As shown in FIG. 3, the organic light emitting diode (OLED) display 103 according to the third embodiment uses a film made of a resin material for the encapsulation member 420. For example, the encapsulation member 420 can be a polyimide (PI) film with excellent heat resistance, chemical resistance, and insulation.

The thin film encapsulation layer 222 is formed in the space that is sealed by the sealant 450 and the encapsulation member 420. Thus, the encapsulation member 420 can be made with a resin-based film even though it has lower vapor transmission resistance than a glass substrate. That is, the encapsulation member 420 can be formed with polyimide that is relatively easy to use in manufacture and that is inexpensive. Also, when the resin-type film is used for the encapsulation member 420, the thickness of the organic light emitting diode (OLED) display 103 can be reduced.

Further, the bonding of the encapsulation member 420 and the display substrate 111 can be supplemented by providing adherence to one surface of the encapsulation member 420 facing the light blocking pattern layer 310 or by adding an adhesive layer (not shown) between the light blocking pattern layer 310 and the encapsulation member 420.

FIG. 3 shows the case of using the light blocking pattern layer 310 for the light control member, and the third embodiment is not limited thereto. The light control member can be the polarizing member 320 in a like manner of the second embodiment.

By the above-noted configuration, the organic light emitting diode (OLED) display 103 according to the third embodiment can improve durability and vapor transmission resistance.

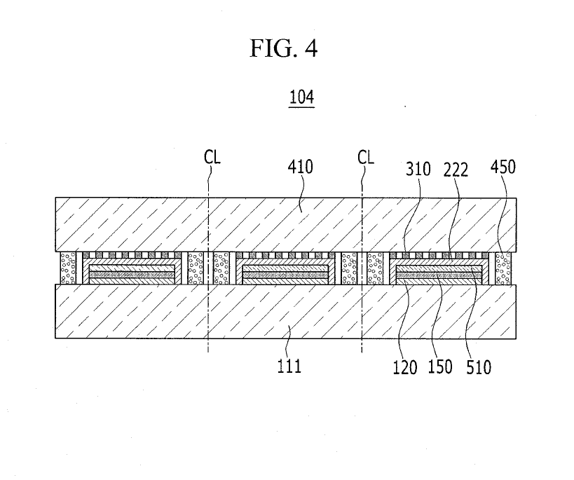

A fourth embodiment will now be described with reference to FIG. 4.

As shown in FIG. 4, the organic light emitting diode (OLED) display 104 further includes a touch sensor 510 between the thin film encapsulation layer 222 and the organic light emitting element 150. In the fourth embodiment, the touch sensor 510 is an in-cell type sensor. Any one of the various types of sensors such as the resistive type sensor, the ultrasonic wave type sensor, and the infrared ray type sensor as well as the capacitive type sensor can be used for the touch sensor 510.

FIG. 4 shows the case of using the light blocking pattern layer 310 for the light control member, and the fourth embodiment is not limited thereto. Therefore, the light control member can be the polarizing member 320 in a like manner of the second embodiment.

Also, the encapsulation member 410 can be a glass substrate in a like manner of the first embodiment, and it can be a film made of a resin-type material in a like manner of the third embodiment.

By the above-noted configuration, the organic light emitting diode (OLED) display 104 according to the fourth embodiment improves durability and vapor transmission resistance, and efficiently suppresses reflection of external light, and can have elements such as the touch sensor 510.

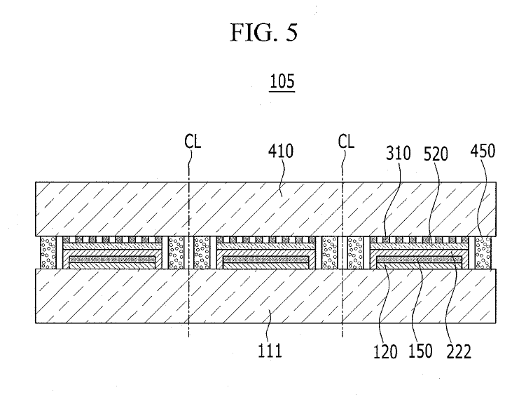

Referring to FIG. 5, a fifth embodiment will now be described.

As shown in FIG. 5, the organic light emitting diode (OLED) display 105 according to the fifth embodiment further includes a touch sensor 520 between the light blocking pattern layer 310 that is a light control member and the thin film encapsulation layer 222. In the fifth embodiment, the touch sensor 520 is an on-cell type sensor. Any one of various types of touch sensors such as the resistive type sensor, the ultrasonic wave type sensor, and the infrared ray type sensor as well as the capacitive type sensor can be used for the touch sensor 520.

In the fifth embodiment, the touch sensor 520 is protected by the encapsulation member 410 along with the light blocking pattern layer 310, so the touch sensor 520 is efficiently prevented from being damaged. Also, the thin film encapsulation layer 222 prevents the organic light emitting element 150 from being damaged while the touch sensor 520 is formed.

FIG. 5 shows the case of using the light blocking pattern layer 310 for the light control member, and the fifth embodiment is not limited thereto. Therefore, the light control member can be the polarizing member 320 in a like manner of the second embodiment.

Also, the encapsulation member 410 can be a glass substrate in a like manner of the first embodiment, and it can also be a film made of a resin-type material in a like manner of the third embodiment.

By the above-noted configuration, the organic light emitting diode (OLED) display 105 according to the fifth embodiment improves durability and vapor transmission resistance, efficiently suppresses reflection of external light, and can have additional elements such as the touch sensor 520.

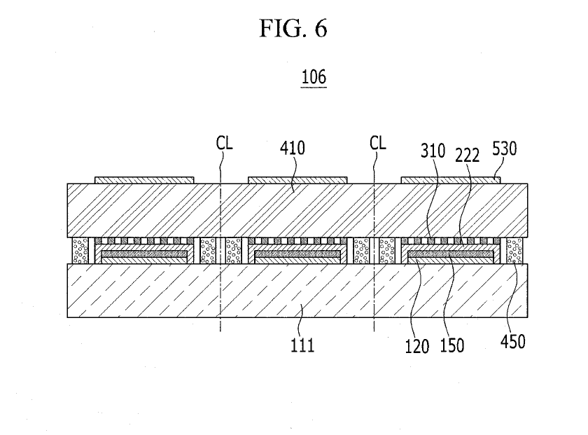

Referring to FIG. 6, a sixth embodiment will now be described.

As shown in FIG. 6, the organic light emitting diode (OLED) display 106 according to the sixth embodiment further includes a touch sensor 530 formed on a surface opposite to the surface of the encapsulation member 410 facing the organic light emitting element 150. In the sixth embodiment, the touch sensor 530 is an add-on type sensor. Any one of types of touch sensors such as the resistive type sensor, the ultrasonic wave type sensor, and the infrared ray type sensor as well as the capacitive type sensor can be used for the touch sensor 530.

In the sixth embodiment, the touch sensor 530 can be relatively easily attached to the organic light emitting diode (OLED) display 106.

FIG. 6 shows the case of using the light blocking pattern layer 310 for the light control member, and the sixth embodiment is not limited thereto. Therefore, the light control member can be the polarizing member 320 in a like manner of the second embodiment.

Also, the encapsulation member 410 can be a glass substrate in a like manner of the first embodiment, and it can be a film made of a resin-type material in a like manner of the third embodiment.

By the above-noted configuration, the organic light emitting diode (OLED) display 106 according to the sixth embodiment improves durability and vapor transmission resistance, efficiently suppresses reflection of external light, and can have additional elements such as the touch sensor 530.

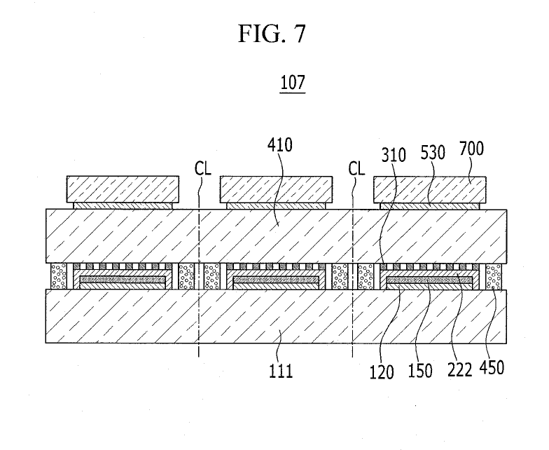

Referring to FIG. 7, a seventh embodiment will now be described.

As shown in FIG. 7, the organic light emitting diode (OLED) display 107 according to the seventh embodiment further includes a touch sensor 530 formed on a surface that opposite to the surface of the encapsulation member 410 facing the organic light emitting element 150, and a protection window 700 bonded to the touch sensor 530 to oppose the encapsulation member 410. In the seventh embodiment, the touch sensor 530 is an add-on type sensor. Any one of various types of touch sensors such as the resistive type sensor, the ultrasonic wave type sensor, and the infrared ray type sensor as well as the capacitive type sensor can be usable for the touch sensor 530.

In the seventh embodiment, the touch sensor 530 can be relatively easily attached to the organic light emitting diode (OLED) display 107, and it is protected by the protection window 700. Also, the protection window 700 can be used for the substrate of the touch sensor 530.

FIG. 7 shows the case of using the light blocking pattern layer 310 for the light control member, and the seventh embodiment is not limited thereto. Therefore, the light control member can be the polarizing member 320 in a like manner of the second embodiment.

Also, the encapsulation member 410 can be a glass substrate in a like manner of the first embodiment, and it can also be a film made of a resin-type material in a like manner of the third embodiment.

By the above-noted configuration, the organic light emitting diode (OLED) display 107 according to the seventh embodiment improves durability and vapor transmission resistance, securely suppresses reflection of external light, and can have additional elements such as the touch sensor 530.

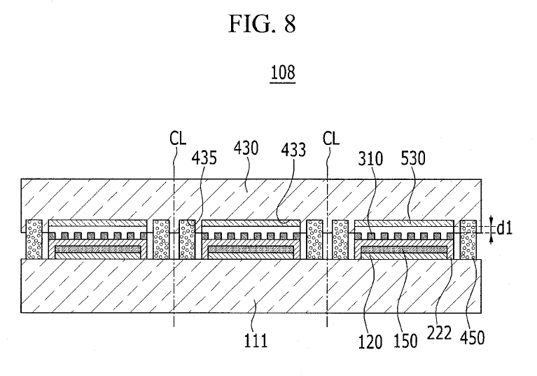

Referring to FIG. 8, an eighth embodiment will now be described.

As shown in FIG. 8, the encapsulation member 430 of the organic light emitting diode (OLED) display 108 according to the eighth embodiment includes a dent 433 that is formed on a surface facing the organic light emitting element 150. A touch sensor 530 is formed in the dent 433 of the encapsulation member 430. In this instance, the touch sensor 530 is distanced from the thin film encapsulation layer 222 covering the organic light emitting element by a predetermined distance d2. The encapsulation member 430 can be used for the substrate of the touch sensor 530. Accordingly, the touch sensor 530 is disposed in the dent 433 of the encapsulation member 430, and this configuration securely protects the touch sensor 530 and reduces the thickness of the organic light emitting diode (OLED) display 108.

Further, the thin film encapsulation layer 222 covering the organic light emitting element 150 and the touch sensor 530 are separated to avoid generation of noise occurring when the touch sensor 530 senses a touch or incorrect operation.

In like manners of the above-described embodiments, any one of the various types of touch sensors such as the resistive type sensor, the ultrasonic wave type sensor, and the infrared ray type sensor as well as the capacitive type sensor can be used for the touch sensor 530.

Also, the encapsulation member 430 further includes an additional dent 435 formed on the surface facing the sealant 450. One end of the sealant 450 is received in the additional dent 435 of the encapsulation member 430. Hence, bonding between the sealant 450 and the encapsulation substrate 430 can be precisely controlled, and damage of the touch sensor 530 that may be occurred when the sealant 450 contacts the touch sensor 530 can be avoided.

FIG. 8 shows the case of using the light blocking pattern layer 310 for the light control member, and the eighth embodiment is not limited thereto. Therefore, the light control member can be the polarizing member 320 in a like manner of the second embodiment.

Also, the encapsulation member 430 can be a glass substrate in a like manner of the first embodiment, and it can also be a film made of a resin-type material in a like manner of the third embodiment.

By the above-noted configuration, the organic light emitting diode (OLED) display 108 according to the eighth embodiment improves durability and vapor transmission resistance, further efficiently suppresses reflection of external light, and can have additional elements such as the touch sensor 530.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display comprising:
a display substrate;
an organic light emitting element formed over the display substrate;
a thin film encapsulation layer formed over the display substrate to cover the organic light emitting element;
an encapsulation member facing the display substrate with the organic light emitting element and the thin film encapsulation layer therebetween;
a sealant surrounding the organic light emitting element and the thin film encapsulation layer, disposed between the display substrate and the encapsulation member, and bonding the display substrate and the encapsulation member; and
a light control member disposed between the encapsulation member and the thin film encapsulation layer, the light control member is configured to suppress a reflection of external light.

2. The organic light emitting diode display of claim 1, wherein the light control member comprises a polarizing member.

3. The organic light emitting diode display of claim 1, wherein the light control member comprises a light blocking pattern layer.

4. The organic light emitting diode display of claim 1, wherein the encapsulation member comprises a substrate made of glass.

5. The organic light emitting diode display of claim 1, wherein the encapsulation member comprises a film made of a resin-based material.

6. The organic light emitting diode display of claim 1, wherein the sealant comprises an epoxy-based material.

7. The organic light emitting diode display of claim 1, which is produced by a process comprising:
forming a plurality of the organic light emitting elements, a plurality of the thin film encapsulation layers, and a plurality of the light control members over a single mother substrate divided into a plurality of sections which are to form a plurality of the display substrates,
bonding the encapsulation member to the mother substrate using the plurality of sealants to form an unfinished product, and
cutting at regions positioned between the sealants surrounding the different organic light emitting elements to divide the unfinished product into a plurality of the organic light emitting diode displays.

8. The organic light emitting diode display of claim 1, further comprising a touch sensor disposed between the organic light emitting element and the thin film encapsulation layer.

9. The organic light emitting diode display of claim 1, further comprising a touch sensor disposed between the light control member and the thin film encapsulation layer.

10. The organic light emitting diode display of claim 1, wherein the encapsulation member comprises a dent that is formed on a surface facing the organic light emitting element, and further comprises a touch sensor formed in the dent of the encapsulation member.

11. The organic light emitting diode display of claim 10, wherein the encapsulation member further comprises an additional dent formed on the surface facing the sealant, and
wherein one end of the sealant is received in the additional dent.

12. The organic light emitting diode display of claim 1, further comprising a touch sensor formed over a surface of the encapsulation member facing away from the organic light emitting element.

13. The organic light emitting diode display of claim 12, further comprising a protection window coupled to the encapsulation member with the touch sensor therebetween.
